(19) United States
(12) Patent Application Publication
(10) Pub. No.: US 2017/0221974 A1
(43) Pub. Date: Aug. 3, 2017

(54) DISPLAY DEVICE

(71) Applicant: Japan Display Inc., Tokyo (JP)

(72) Inventors: Yasukazu KIMURA, Tokyo (JP); Norio Oku, Tokyo (JP); Toshihiko Itoga, Tokyo (JP); Takeshi Kuriyagawa, Tokyo (JP); Jun Fujiyoshi, Tokyo (JP); Takuma Nishinohara, Tokyo (JP)

(21) Appl. No.: 15/492,050

(22) Filed: Apr. 20, 2017

Related U.S. Application Data
(63) Continuation of application No. 14/599,011, filed on Jan. 16, 2015.

(30) Foreign Application Priority Data
Jan. 21, 2014 (JP) 2014-008480

(51) Int. Cl. H01L 27/32; H01L 51/52

(52) U.S. Cl. CPC H01L 27/3246; H01L 51/5271; H01L 27/3258; H01L 51/5209

(57) ABSTRACT

A display device is comprising an insulating layer provided above a substrate, a pixel electrode provided on the insulating layer, a bank layer covering a periphery edge part of the pixel electrode, a light emitting layer provided across to a surface layer part of the bank layer from the pixel electrode, and a common electrode provided on the light emitting layer, wherein the pixel electrode including a slanting region having a periphery edge part becoming higher compared to a center region, and an edge part of the bank layer overlaps the slanting region of the pixel electrode.

### CROSS REFERENCE TO RELATED APPLICATIONS

This application is based upon and claims the benefit of priority from the prior Japanese Patent Application No. 2014-008480, filed on Jan. 21, 2014, the entire contents of which are incorporated herein by reference.

### FIELD

The present invention is related to a display device and the form of the invention disclosed is related to a structure of a pixel provided with a light emitting device.

### BACKGROUND

Since a display device formed with a pixel using a light emitting device using an organic electroluminescence material does not require a back light source as in a liquid crystal display device, such display devices are expected to be used to realize thin displays, curved displays or displays having flexibility. Realization of a display having flexibility is not only for the purpose of thinness but also leads to the development of new purposes in the field of display devices.

A display device which can realizes thinness is formed by stacking layers of thin films of light emitting devices. A light emitting device includes a cathode, a light emitting layer including an organic electroluminescent material and an anode are laminated. The light emitting layer may also have a structure in which thin films have functions such as a hole transport layer, a light emitting layer and electron transport later are stacked. Even when the thickness of all these layers is added together, the light emitting layer only has a thickness of a few hundred nanometers. Because the light emitting device has a structure in which this type of thin light emitting layer is sandwiched between a cathode and anode, it is necessary to ensure that the cathode and anode do not electrically short.

In a display device, although a pixel electrode (an electrode corresponding to an electrode on either an anode or cathode side) is provided in a matrix shape and a light emitting layer is provided above this, in order to prevent electrical shorting with a counter electrode (an electrode corresponding to an electrode on either a cathode or anode side), it is preferred that an insulating layer is provided which covers the edge part of the pixel electrode. This insulating layer is called a bank layer since it corresponds to a bank which bulges with respect to a pixel electrode.

A bank layer relieves a step in an edge part of a pixel electrode, and it is preferred to have a gently sloping edge part shape with a tapered angle in order to prevent electrical shorting between an anode and cathode. An example in which the taper angle of the edge part in which a bank layer overlaps a pixel electrode is preferred to be 30 degrees or less is disclosed in Japanese Laid Open Patent 2003-233332.

By making the taper angle of an edge part of a bank layer which overlaps a pixel electrode 30 degrees or less, it is expected that coat ability of a step of a light emitting layer is improved and stress on the light emitting layer is relieved when a panel in a sheet display is bent. In this way, peeling of a light emitting layer is prevented and it is expected that it is possible to prevent the occurrence of unintended non-light emitting regions (dark spots).

However, when the taper angle of a bank layer is reduced into a gently sloping slanting surface, the region of the bank layer becomes larger. Since the upper side of a bank layer becomes a non-light emitting region, a problem occurs where the aperture ratio of a pixel drops. In addition, in the case of achieving an improvement in pixel density and high resolution, because the interval between pixels (pixel pitch) cannot be narrowed, high definition is obstructed.

### SUMMARY

According to one embodiment of the present invention, a display device is comprising an insulating layer provided above a substrate, a pixel electrode provided on the insulating layer, a bank layer covering a periphery edge part of the pixel electrode, a light emitting layer provided across to a surface layer part of the bank layer from the pixel electrode, and a common electrode provided on the light emitting layer, wherein the pixel electrode including a slanting region having a periphery edge part becoming higher compared to a center region, and an edge part of the bank layer overlaps the slanting region of the pixel electrode.

According to one embodiment of the present invention, a display device is comprising a first insulating layer provided above a substrate, a pixel electrode provided on the first insulating layer, a bank layer covering a periphery edge part of the pixel electrode, a light emitting layer provided along a surface layer part of the bank layer from the pixel electrode, and a common electrode provided on the light emitting layer, wherein the pixel electrode including a slanting region having a periphery edge part becoming higher compared to a center region, a second insulating layer exists between a slanting region of the pixel electrode and the first insulating layer, and an edge part of the bank layer overlaps the slanting region of the pixel electrode.

### BRIEF DESCRIPTION OF THE DRAWINGS

FIG. 1 is a diagram showing a structure of display device related to one embodiment of the present invention;

FIG. 2 is a planar view diagram showing a structure of display device related to one embodiment of the present invention;

FIG. 3 is a cross-sectional view diagram showing a structure of display device related to one embodiment of the present invention;

FIG. 4 is a cross-sectional view diagram for explaining a structure of a step part in a pixel of a display device related to one embodiment of the present invention;

FIG. 5A is a cross-sectional view diagram for explaining a manufacturing method of a display device related to one embodiment of the present invention;

FIG. 5B is a cross-sectional view diagram for explaining a manufacturing method of a display device related to one embodiment of the present invention;

FIG. 6 is a cross-sectional view diagram showing a structure of a pixel of a display device related to one embodiment of the present invention;

FIG. 7 is a cross-sectional view diagram showing a structure of a pixel of a display device related to one embodiment of the present invention; and

FIG. 8 is a planar view diagram showing a structure of a pixel of a display device related to one embodiment of the present invention.

### DESCRIPTION OF EMBODIMENTS

Each embodiment of the present invention is explained below while referring to the drawings. Furthermore, the disclosure is merely one example and various modifications which conform to the premise of the invention and which could be easily conceived of by person ordinarily skilled in the art are included within the scope of the present invention. In addition, in order to further clarify explanation, the drawings may be expressed schematically with respect to the width, thickness and shape of each part compared to actual appearance and are only examples and do not limit the interpretation of the present invention. In addition, in the specification and each drawing the same reference symbols are attached to the same devices that have previously been described or already exist in previous drawings and therefore a detailed explanation is sometimes omitted where appropriate. In the present specification, in the case where certain components or areas are present “over” or “under” and “above” or “below” other components or areas, as long as there are no particular limitations, this includes not only the case where components or areas are directly above or directly below other components or areas but also the case where components or areas are above or below other components or areas with other structural components provided in between.

### First Embodiment

### [Structure of a Display Device]

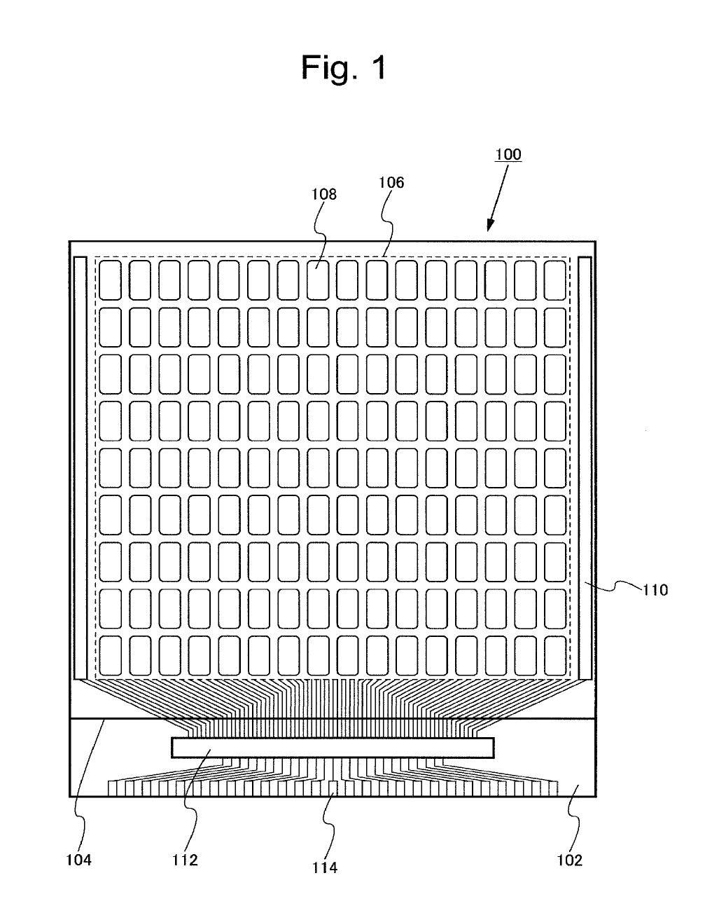

FIG. 1 shows a structure of a display device related to one embodiment of the present invention. The display device 100 is provided with a pixel region 106 provided with a plurality of pixels 108 in an element substrate 102. A sealing substrate 104 is provided facing the element substrate 102 in order to cover the pixel region 106. The sealing substrate 104 and element substrate 102 are fixed using a seal member. A filler material may be provided within a region enclosed by the seal member between the sealing substrate 104 and element substrate 102. In addition, a scanning line drive circuit and data line drive circuit which send signals to a pixel 108 may be provided in an exterior side region of the pixel electrode 106 in the element substrate 102. In addition, an input terminal part 114 is provided in the element substrate 102.

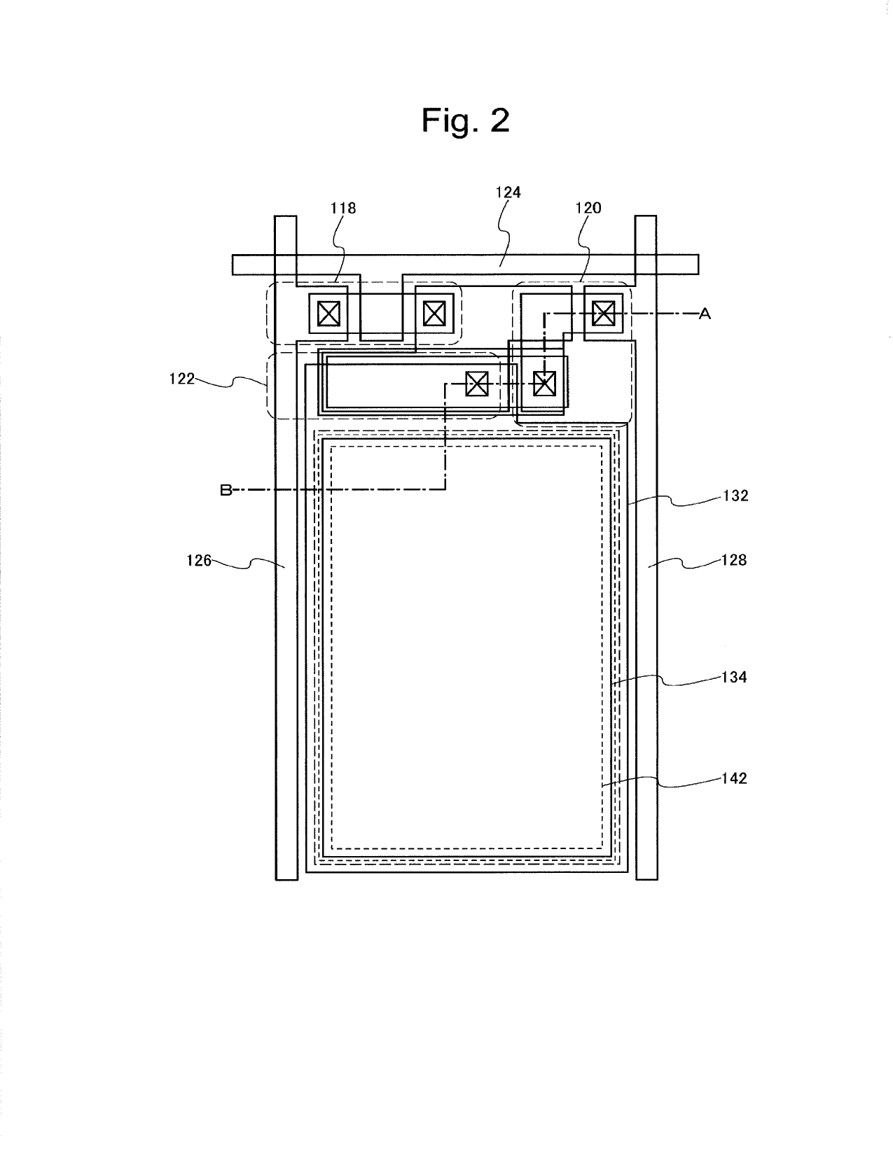

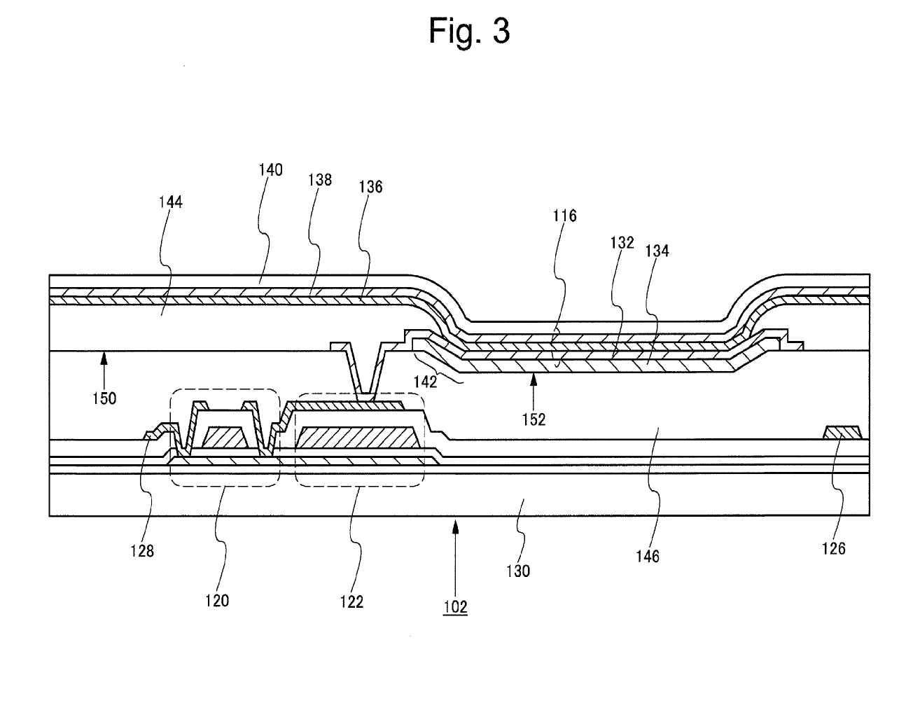

An example of a pixel is explained while referring to FIG. 2 and FIG. 3. FIG. 2 shows a planar view of a pixel and a cross-sectional structure along the dotted line A-B shown in FIG. 2 is shown in FIG. 3. The following explanation uses both FIG. 2 and FIG. 3.

A pixel 108 includes a plurality if transistors and at least one capacitor part. In the present embodiment, the pixel 108 includes two transistors, a first transistor (selection transistor) 118 and second transistor (drive transistor) 120, one capacitor part 122 and a light emitting device 116. The light emitting device 116 may be formed using a light emitting layer including an organic electroluminescence material for example.

The first transistor 118 is controlled by a switch via a scanning line 124 which receives a signal from a scanning line drive circuit, reads a video signal from a data line 126 at certain timing and provides a voltage to the gate of the second transistor 120 according to the video signal. The gate voltage of the second transistor 120 provided by the first transistor 118 is held by the capacitor part 122. The drain of the second transistor 120 is connected to a power source line 128 and the source is connected to the pixel electrode 132. The light emitting time period and intensity of the light emitting device 116 is controlled by a current (drain current) which is controlled by the gate potential of the second transistor 120.

As is shown in FIG. 3, the light emitting device 116 is formed by stacking a pixel electrode 132, light emitting layer 136 and common electrode 138. In the present embodiment, although the light emitting layer 136 is formed using a low molecular or high molecular organic material, there is no particular limit to the organic material or later structure used in the present invention. For example, in the case where a low molecular organic material is used for the light emitting layer 136, in addition to a light emitting layer including an organic material with light emitting properties, a hole transport later or carrier transport layer of an electron transport layer may be added to sandwich the light emitting layer.

A light emitting layer which emits each color, red (R), green (G) and blue (B) or a white light emitting layer which emits light in a wide band in the visible light wavelength band can be used as the light emitting layer which is included in the light emitting layer 136. It is possible to realize a display device with a color display by combining each of these color light emitting layers or white light emitting layer and a color filter.

Since the light emitting layer 136 degrades due to moisture, a sealing film 140 is provided on an upper layer of the common substrate 138. The sealing layer 140 is preferred to be formed using an insulating material. For example, it is possible to effectively block moisture by forming the sealing film 140 using silicon nitride as an inorganic material. In addition, it is possible to form the sealing film 140 provided with barrier properties and flexibility by using a parylene polymer as an organic material.

Although light can be emitted from the light emitting layer 136 using a bottom emission type which emits light to the side of the pixel electrode 132 or a top emission type which emits light towards the common electrode 138 side, in the example shown in FIG. 3, a top emission structure is adopted by provided a reflection plate 134 on the rear side of the pixel electrode 132. The reflection plate 134 is preferred to be formed using a metal with a high level of reflectivity such as aluminum. The pixel electrode 132 is preferred to be an electrode with translucency formed using a transparent conductive film. In the case of a top emission type, the common electrode 138 may also be formed using a material with translucency.

The pixel electrode 132 is not flat but includes a form wherein the periphery edge part is higher compared to the center part even when a contact part with the second transistor 120 is removed. In other words, the pixel electrode 132 can be seen with a lower center part than the periphery edge part. The form of the pixel electrode 132 is not step shaped but is a tape shape in which the height gradually changes in the periphery edge part.

The form of this type of slanting region 142 can be realized for example by making the thickness of the periphery edge part thinner compared to the thickness of the center region of the pixel electrode 132. In addition, as is shown in FIG. 3, a second surface 152 is provided on a lower position with respect to a first surface 150 of the insulating layer 146 on a ground side of the pixel electrode 132, and a transition region between the first surface 150 and second surface 152 may be matched with the form of the slanting region 142. The second surface 152 in the insulating layer 146 can be viewed as a concave region corresponding to a low region compared to the first surface 150. In addition, by arranging the pixel electrode 132 along the first surface 150 from the second surface 152, it is possible to arrange the slanting region 142 on the periphery edge the pixel electrode 132 as described above. Although the insulating layer 146 may be an inorganic insulation material or organic insulation material, it is preferred to use an insulation material such as an acrylic resin so that the surface can be planarized.

The edge of part of the bank layer 144 which covers the periphery edge of the pixel electrode 132 is provided so as to overlap the slanting region 142. The shape of the edge part of the bank layer 144 is not a straight up edged surface but is provided so as to be a taper shaped slanting surface. In addition, the edge part of the bank layer 144 may also have a curved shape in which the film thickness gradually increases such that the radius curvature changes consistently. The bank layer 144 is preferred to be formed using an insulation material, for example an organic insulation material such as polyimide.

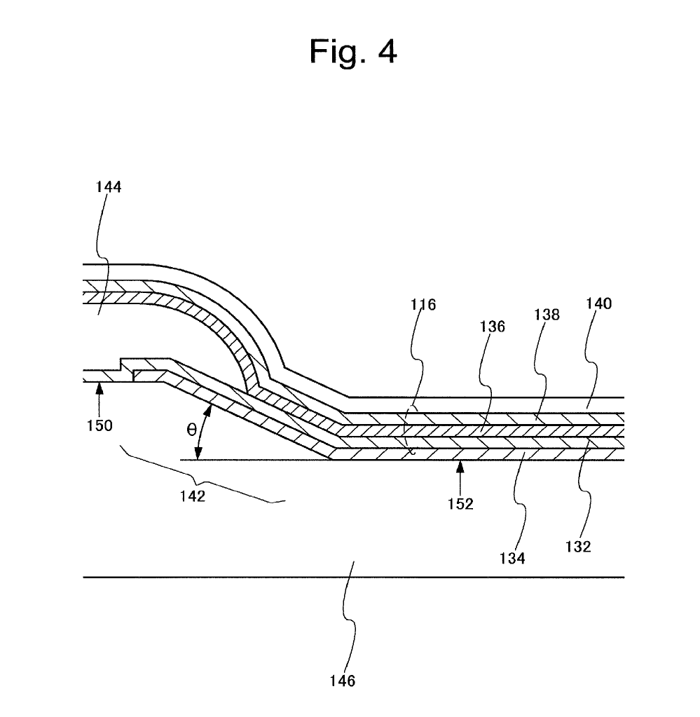

FIG. 4 shows a partial expanded view for explaining the relationship between the slanting region 142 of the pixel electrode 132 and the edge part of the bank layer 144. A case where a concave part is provided in the insulating layer 146 is shown in FIG. 4 and includes a bottom surface of the concave part, that is, the slanting region 142 from the second surface 152 to the first surface 150. The pixel electrode 132 is provided so as to link with the first surface 150 via the slanting region 142 from the second surface 152. As a result, the center region of the pixel electrode 132 is located in the second surface 152 and the periphery edge part is located in the slanting region 142. Using this form, the slanting surface in the slanting region 142 of the pixel electrode 132 and the slanting surface in the edge part of the bank layer are provided to be continuously.

When the first surface 150 and second surface 152 are flat, an angle θ of the slanting region 142 is preferred to be 30 degrees or less with respect to this flat surface. When this angle is 30 degrees or less, the interior of the slanting region 142 does not have to be constant, the slanting surface may change consistently or inconsistently.

The light emitting layer 136 is provided continuously along the surface of the bank layer 144 from the upper surface of the pixel electrode 132. In this case, from the view of the light emitting layer 136, the light emitting layer 136 and edge part of the bank layer 144 overlaps the slanting surface of the insulation layer 146. Therefore, the light emitting layer 136 is flat shape on the pixel electrode, and inclination at the edge part of the bank layer is relieved.

As in a conventional example, the pixel electrode has a flat form and in the case where a slanting surface is provided only in the edge part of a bank layer, a step due to the bank layer is relieved only by the angle of the slanting surface. In this case, if the slanting angle of the edge part of the bank layer is not reduced, the light emitting layer significantly curves at the step part of the pixel electrode and bank layer and stress can be concentrated on this part. Consequently, when a force which bends an element substrate is applied, stress is concentrated on this bent part which leads to the light emitting layer peeling away from the pixel electrode.

However, as in the present embodiment, by overlapping the slanting region 142 in the periphery edge part of the pixel electrode with the edge part and slanting surface of the bank layer 144, synergy effects are produced without having to reduce only the slanting angle in the edge part of the bank layer 144. In whichever case, by arranging the edge part of the bank layer 144 so that it overlaps with the slanting region 142 provided in the periphery edge part of the pixel electrode 132, even if the slanting angle itself in the edge part of the bank layer 144 is not significantly reduced, the step from the edge surface of the bank layer 144 to the slanting surface of the insulating layer 146 is relieved.

According to the present embodiment, even when the thickness of the bank layer 144 is the same as a conventional example, it is possible to substantially reduce the slanting angle of the edge part of the bank layer 144 from the slanting angle of the slanting region 142. As a result, because it is not necessary to make the bank layer 144 thinner, it is possible to prevent defects such as a difference in the dimensions of film thickness and uneven external appearance.

### [Manufacturing Method]

It is possible to form the slanting region 142 in the periphery part of the pixel electrode 132 as described above so that a concave region is formed in the insulating layer 146 on the ground side of the pixel electrode 132 and arrange the pixel electrode 132 along that surface. Because processing of the insulating layer 146 is an etching process for forming a contact hole for connecting the pixel electrode 132 with the source of the second transistor 120, it is possible to perform this process using the same method if the etching depth is controlled. In this case, if an etching mask is manufactured with a different depth using halftone exposure, it is possible to form a contact hole and a concave region simultaneously.

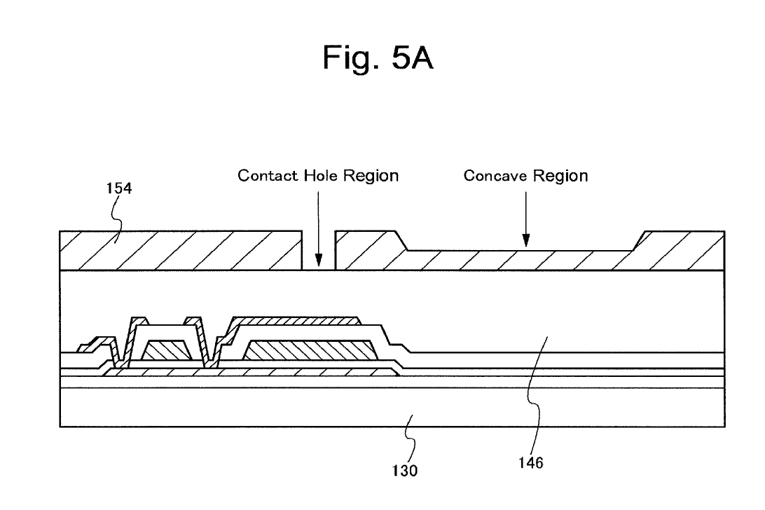

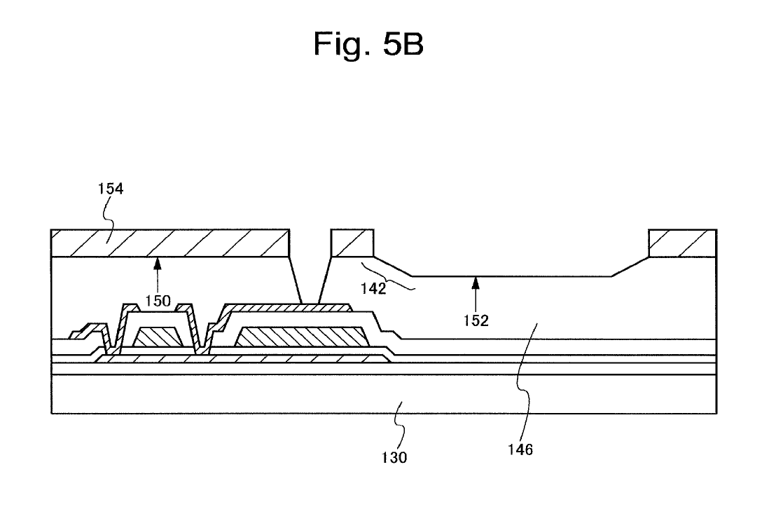

FIG. 5A and FIG. 5B show a process for forming a contact hole in the insulating layer 146 and a concave region using halftone exposure. Halftone exposure refers to exposure using a halftone photo-mask. A halftone photo-mask is an exposure method in which regions with different transparency ratios (intermediate transparency ratio) are provided in advance within a mask pattern and etching mask depths formed with a photosensitive resin are made to be different by performing intermediate exposure of a region corresponding to that region. Furthermore, it is also possible to use a grey-tone exposure as a similar exposure method as a replacement in the present embodiment. A grey-tone method is a method in which a slit is formed below a resolution of the exposure machine and intermediate exposure is achieved by blocking a part of the light using the slit. In either exposure method, it is possible to express three exposure levels in one exposure “part to be exposed”, “intermediate exposure part” and “part not to be exposed” and it is possible to form etching mask with at least two different depths after development.

FIG. 5A shows a step which forms an etching mask above the insulating layer 146 using halftone exposure. In the case where the etching mask 154 is formed using a positive type photosensitive resist material, a halftone mask used in the exposure is used for complete exposure for forming a contact hole and intermediate exposure for forming the concave region. In this way, in the region which is completely exposed, the photosensitive resist material completely removed and in the intermediate exposed region, the thickness of the etching mask is formed thinner compared to the non-exposed parts. In this case, as is shown in FIG. 5A, the transparency ratio of the half-tone mask may be controlled so that the thickness of the etching mask changes consistently in an interface region between the intermediate exposure regions and non-exposed region so that the slanting region 142 is effectively formed.

FIG. 5B shows the state of the insulating layer 146 after etching. In the etching process, it is possible to make the etching depth of the insulating layer 146 in the exposure region and intermediate exposure region different by etching the insulating layer 146 and gradually etching the etching mask. In addition, because there is a taper region at the interface region between the intermediate exposure region and non-exposure region and etching is performed while etching this taper region, it is possible to effectively form the slanting region 142. In this case, because the etching mask also remains in the non-exposed regions, the first surface 150 of the insulating 146 remains unchanged and the surface 146 of the insulating layer 146 is etched to form the second surface 152 in the intermediate exposure region.

Following this, as is shown in FIG. 3, the reflection plate 134 and pixel electrode 132 are formed from the second surface 152 to the first surface 150, and the display device is manufactured by forming the bank layer 144, light emitting layer 136 and common substrate 138.

In the present embodiment, the substrate 130 may be a glass substrate or a flexible substrate formed from an organic resin material. For example, polyimide may be used as the organic resin material used for a flexible substrate. In the case where polyimide is used for a substrate, because it is possible to provide a substrate with a thickness of 100 micro-meters of less, for example from 10 micro-meters to 50 micrometers, it is possible to realize a flexible display device. Furthermore, although not shown in the diagram, a thermal diffusion sheet may be arranged on the rear surface side (opposite side to the surface on which the light emitting device is provided) of a polyimide substrate when a polyimide material is used as the substrate 130.

In the case of such as flexible display device, by arranging a slanting region 142 in the periphery edge part of the pixel electrode 132 as shown in the present embodiment and the edge part of the bank layer 144 to overlap the slanting region, it is possible to relieve stress applied to the light emitting layer 136 in the edge part of the bank layer 144. In this way, it is possible to prevent the light emitting layer 136 from peeling.

According to the present embodiment, by arranging a slanting region 142 in a periphery edge part of the pixel electrode 132 and the bank layer 144 to overlap at least a part of the slanting region 142 and the light emitting layer 136 along the slanting region 142, it is possible to relive the concentration of stress on the light emitting layer on the light emitting layer 136 in the edge part of the bank layer 144. This structure is also effective for relieving stress on the region where the substrate bends in the case of realizing a flexible sheet display by forming the substrate 130 in the element substrate 102 using an organic resin material. Because of this effect, it is possible to prevent the light emitting layer 136 from peeling from the pixel electrode 132. In addition, it is possible to prevent the occurrence of a non-light emitting region in the display device 100.

### MODIFIED EXAMPLE 1

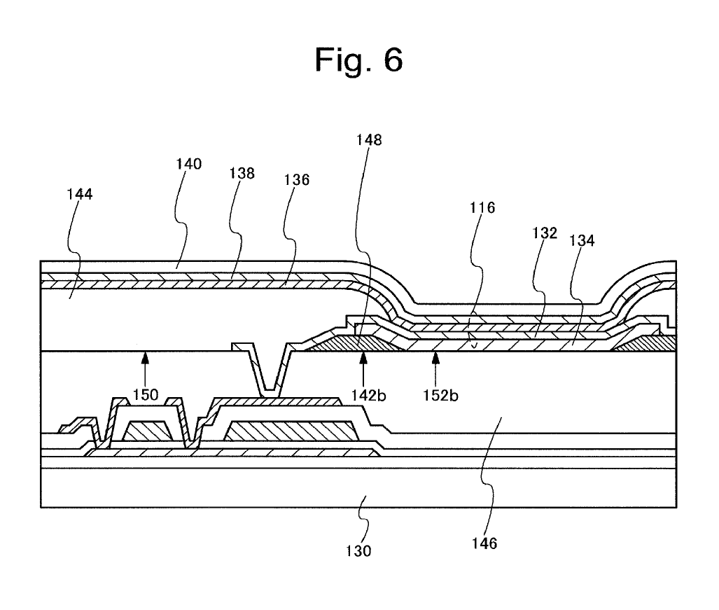

In FIG. 3, although the slanting region 142 is realized by provided a concave region by etching the insulating layer 146, as is shown in FIG. 6, a slanting region 142b may be formed by provided a second insulating layer 148 in a region corresponding to the periphery edge part of the pixel electrode 132 above the insulating layer 146. In this case, the side edge part of the second insulating layer 148 is preferred to include the same slanting surface as the slanting region 142 provided in the insulating layer 146.

According to FIG. 6, although the height of the first surface 150 and the second surface 152b provided with pixel electrode 132 is the same, because the convex shaped second insulating layer 148 is provided in the periphery edge part of the pixel electrode 132, the same effects that are explained using FIG. 3 also apply as a function of the slanting region 142b. In this way, it is possible to obtain the same main structure as in the first embodiment with the display device related to the present modified example.

### MODIFIED EXAMPLE 2

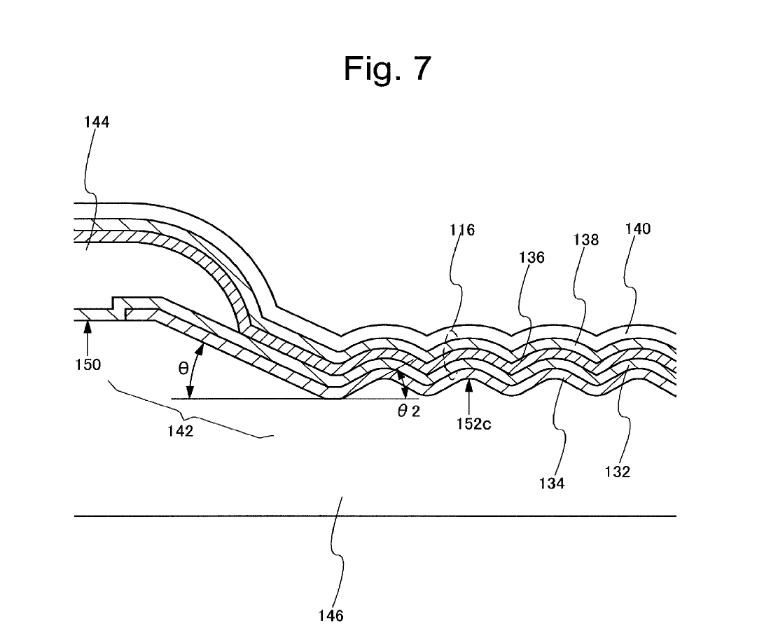

As is shown in FIG. 7, the second surface of the insulating layer 146 located on the ground side of the pixel electrode 132 may be provided to have an uneven shape. The height of the convex part of the uneven shape in the second surface 152c may be the same as the height of the first surface or lower. In either case, the angle 82 of the slanting surface in the uneven shape is preferred to be the same as the slanting angle θ of the slanting region 142.

This type of uneven shape can be similarly processes using a half-tone mask or grey-tone mask when forming the slanting region 142 by etching the insulating layer 146.

Because the pixel electrode 132 is formed along the second surface 152c which if formed in an uneven shape, the surface of the pixel electrode 132 also includes a gently sloping uneven shape. In addition, in the case where there is reflection plate 134 on the lower side of the pixel electrode 132, this surface functions as a diffusion reflection surface. In this way, it is possible to reduce the guided light wave which is trapped within the light emitting layer 136.

In addition, when observing a screen from the display screen side of the display device, it is possible to make the pixel region 106 into a mirror using the effects of the reflection plate 134 and prevent reflection of the viewer or other ones. Furthermore, by making the surface of the pixel electrode 132 into an uneven shape, because the actual surface area of the pixel electrode is increased, it is possible to increase contrast.

In the modified example shown in FIG. 7, because the uneven shape within the pixel electrode 132 has the same slanting angle as the slanting angle of the slanting region 142, local stress in not applied in the light emitting layer 136 even in the case when a panel is bent. Therefore, it is possible obtain the same effects as the main structure in the first embodiment. Furthermore, the uneven shape in the second surface 152c in FIG. 7 and the uneven shape in the pixel electrode 132 may have a structure combined with the second insulating layer 148 shown in FIG. 6.

### Second Embodiment

In the present embodiment, the form of a bank layer different to that in the first embodiment is exemplified in the bank layer which covers the periphery edge part of a pixel electrode.

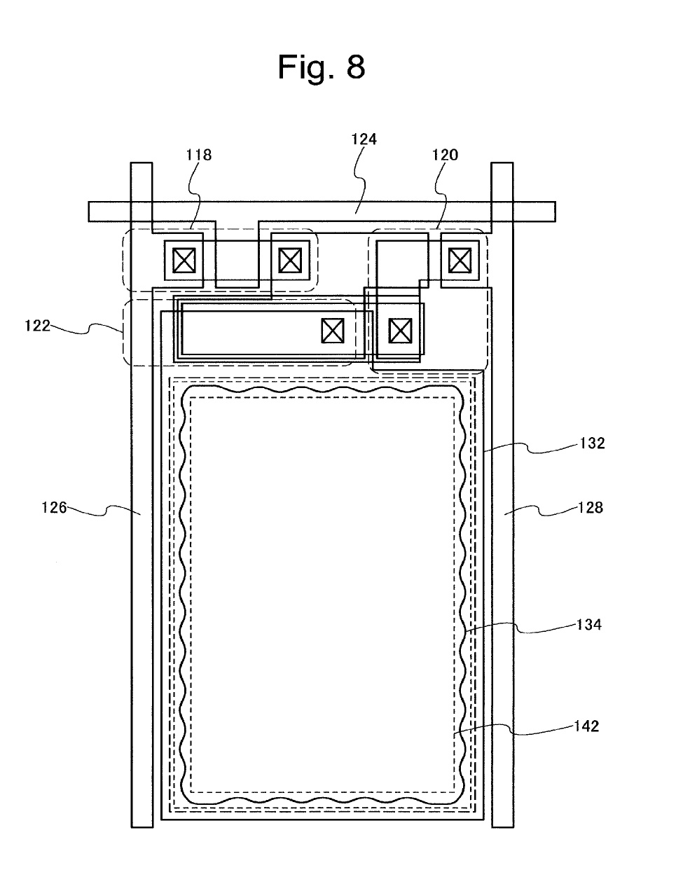

FIG. 8 shows a planar view of a pixel. In FIG. 8, the structure of the first transistor 118, second transistor 120 and capacitor part 122 is the same as in the first embodiment. In addition, the structure of the pixel electrode 132 and the slanting region 142 in the periphery edge is also the same as in the first embodiment.

In FIG. 8, the edge part above the slanting region 142 of the bank layer 144b which covers the periphery edge part of the pixel electrode 132 is not provided in a straight line along the pixel electrode 132, but includes a curved shape which bends in a wave shape. By bending the edge part of the bank layer 144b into a wave shape, and overlapping the edge part with the slanting region 142 of the pixel electrode 132, it is possible to avoid a concentration of stress on the light emitting layer 136 formed along the surface of the pixel electrode 132 and bank layer 144b and disperse the stress in a plurality of directions.

According to the present embodiment, because the slanting region 142 in the periphery edge part of the pixel electrode 132 and the edge part of the bank layer 144 are provided so as to overlap in at least one part of the slanting region 142, it is possible to obtain the same effects as in the first embodiment. Furthermore, because the edge part of the bank layer has a curved shape bend into the shape of a wave, it is possible to increase the effects of relieving stress on the light emitting layer 136. This structure can also be effectively applied to relieving stress which affects the region when bending a substrate in the case of forming the substrate 130 in the element substrate 102 in the case of realizing a flexible sheet display. With these effects, it is possible to prevent the light emitting layer 136 from peeling from the pixel electrode 132. In addition, it is possible to prevent the occurrence of a non-light emitting region in the display device 100. The present embodiment can be realized by combining with the first embodiment.

What is claimed is:

1. A display device comprising:
a substrate having a flat surface;
an insulating layer on the flat surface;
a pixel electrode on the insulating layer;
a bank layer on the pixel electrode;
an organic EL layer on the bank layer and the pixel electrode; and
a common electrode on the organic EL layer,
wherein
the insulating layer includes a concave portion which overlaps with the flat surface,
the pixel electrode entirely covers the concave portion,
the pixel electrode includes a slanting surface, a center surface surrounded by the slanting surface, and a first interface between the slanting surface and the center surface,
the slanting surface has an angle greater than zero degrees with respect to the flat surface,
the bank layer includes an aperture exposing the center surface and a part of the slanting surface, and
an edge of the aperture is between an edge of the pixel electrode and the center surface.

2. The display device according to claim 1, wherein
the pixel electrode further includes a periphery edge part surrounding the slanting surface, and a second interface between the periphery edge part and the slanting surface,
the periphery edge part and the second interface is covered with the bank layer, and
the first interface is not covered with the bank layer.

3. The display device according to claim 2, wherein
the organic EL layer makes a contact with the center surface, the first interface, and the part of the slanting surface, and
the organic EL layer does not make a contact with the second interface.

4. The display device according to claim 1, wherein
the edge of the aperture is curved in a wave shape in plan view.

5. The display device according to claim 1, wherein
the slanting surface has the angle of 30 degrees or less with respect to the flat surface.

6. The display device according to claim 1, wherein
the center surface has a flat shape.

7. The display device according to claim 1, wherein the center surface has an uneven shape.

8. The display device according to claim 7, wherein
a surface of the uneven shape has an angle of 30 degrees or less with respect to the flat surface.

9. The display device according to claim 1, wherein
the pixel electrode has a translucency, and
a reflection plate is between the substrate and the pixel electrode.
